(19) United States
(12) Patent Application Publication
(10) Pub. No.: US 2026/0336045 A1
(43) Pub. Date: Oct. 29, 2026

(54) Surface Inspecting Device

(71) Applicant: Hitachi High-Tech Corporation, Minato-ku, Tokyo (JP)

(72) Inventors: Haruki KOIZUMI, Tokyo (JP); Keiichiro HOSOBUCHI, Tokyo (JP); Masaya YAMAMOTO, Tokyo (JP); Katsuhiko KIMURA, Tokyo (JP)

(21) Appl. No.: 19/120,474

(22) PCT Filed: Oct. 11, 2022
(86) PCT No.: PCT/JP2022/037920

§ 371 Date: Apr. 11, 2025

(51) Int. Cl. B23Q 3/00; G01N 21/95

(52) U.S. Cl. CPC B23Q 3/00; G01N 21/9501; G01N 2201/1035; Y10S 269/909; Y10T 29/49998

(57) ABSTRACT

A surface inspecting device (1) according to the present invention comprises: a plate-shaped sample holding member (3) capable of holding a sample (2); a rotation drive unit (19) for rotating the sample holding member (3); a supporting member (21) that is fixed to the sample holding member (3) and the rotation drive unit (19) and supports the sample holding member (3); and a sample drive unit (11) that displaces the sample holding member (3) in the height direction relative to the rotation drive unit (19). The supporting member (21) comprises a first supporting member (22) and a plurality of second supporting members (23) that support the first supporting member (22). The first supporting member (22) is a plate-shaped member positioned between the sample holding member (3) and the rotation drive unit (19), and is displaceable in the height direction relative to the sample holding member (3) and the rotation drive unit (19). A part of the plurality of second supporting members (23) is fixed to the sample holding member (3), while the remainder are fixed to the rotation drive unit (19).

### TECHNICAL FIELD

The present invention relates to a surface inspecting device for inspecting a sample such as a wafer.

### BACKGROUND ART

In the manufacturing process of semiconductor devices, a surface inspecting device for inspecting the presence or absence of foreign substances adhering to a surface of a sample such as a wafer and the presence or absence of defects in the surface is used. The surface inspecting device irradiates a surface of a rotating plate-shaped sample with a laser light beam and moves the sample in the radial direction to inspect the entire surface of the sample. When foreign substances or defects are present on the surface of the sample, the laser light beam irradiated on the sample is scattered. The surface inspecting device receives the scattered light with a detection optical system to detect the foreign substances and defects, and identifies the position of the foreign substances and defects on the sample based on a rotation angle and a radial position of the sample.

In response to the miniaturization of semiconductor devices, the surface inspecting device is required to improve the sensitivity of detecting foreign substances and defects. As a method of improving the detection sensitivity, shortening the wavelength of laser light beam is being pursued. The shorter the wavelength of laser light, the shallower the depth of focus in the optical system, and consequently, when the height position of the sample surface varies during inspection, the position of the sample surface may deviate from the acceptable focus range of the optical system, which may result in a decrease in detection sensitivity or a shift in the detection position.

To address this problem, an example of a device capable of driving a sample in a direction perpendicular to the surface of the sample (up-and-down direction) while rotating the sample is described in WO2011/125260 (PTL1). The driving device described in PTL1 can drive the stage in an up-and-down direction (in a Z direction) and a rotating direction (in a Oz direction) based on the up-and-down direction as the central axis. The stage is driven in the Z direction by an actuator that includes a rotor having a plurality of permanent magnets and a stator having a coil for driving the stage in the Z direction.

### CITATION LIST

### Patent Literature

PTL1: WO2011/125260A

### SUMMARY OF INVENTION

### Technical Problem

In a related surface inspecting device, while the sample is being rotated and driven in the up-and-down direction (in a focus direction), when the sample is inclined and the surface of the sample is no longer perpendicular to the focus direction, the height position (the position in the focus direction) of the surface of the sample changes according to a radial position of the sample. In this case, the height position of the surface of the sample varies and is out of the acceptable focus range of the optical system, and there is a possibility that accurate inspection may not be possible. Therefore, in order to accurately inspect the sample, it is necessary to accurately determine the position of the sample by driving the sample accurately in the focus direction while keeping the inclination of the sample small. In the related techniques such as techniques described in PTL1, it is difficult to accurately drive the sample in the focus direction to accommodate such variations in the height position of the surface of the sample.

An object of the present invention is to provide a surface inspecting device capable of accurately driving a sample in the focus direction (height direction).

### Solution to Problem

A surface inspecting device according to the present invention may include a sample holding member having a plate shape and capable of holding a sample, a rotation drive unit configured to rotate the sample holding member, a supporting member fixed to the sample holding member and the rotation drive unit and configured to support the sample holding member, and a sample drive unit configured to displace the sample holding member relative to the rotation drive unit in a height direction. The supporting member includes a first supporting member and a plurality of second supporting members supporting the first supporting member. The first supporting member is a plate-shaped member positioned between the sample holding member and the rotation drive unit, and is displaceable in the height direction relative to the sample holding member and the rotation drive unit. Some of the plurality of second supporting members are fixed to the sample holding member, and the remainder are fixed to the rotation drive unit.

### Advantageous Effects of Invention

According to the present invention, it is possible to provide a surface inspecting device capable of accurately driving a sample in the focus direction (height direction).

### BRIEF DESCRIPTION OF DRAWINGS

FIG. 1 is a diagram illustrating a configuration of a surface inspecting device according to a first embodiment of the present invention.

FIG. 2 is a diagram illustrating a sample drive unit and a supporting member of the surface inspecting device according to the first embodiment.

FIG. 3 is a cross-sectional view in an XZ plane illustrating the sample drive unit and the supporting member of the surface inspecting device according to the first embodiment.

FIG. 4 is a diagram illustrating an arrangement of a first magnet provided on a yoke and a first coil according to the first embodiment.

FIG. 5 is a diagram illustrating an arrangement of a second magnet provided on the yoke and a second coil according to the first embodiment.

FIG. 6 is a top view illustrating an arrangement of a sample holding member and a supporting member in a turntable according to the first embodiment.

FIG. 7A is a schematic diagram illustrating a deformation of the supporting member when the sample holding member is driven in a focus direction according to the first embodiment, and is a diagram illustrating the sample holding member in a non-displaced state.

FIG. 7B is a schematic diagram illustrating a deformation of the supporting member when the sample holding member is driven in the focus direction according to the first embodiment, and is a diagram illustrating the sample holding member displaced in the focus direction without being inclined to a plane perpendicular to the focus direction.

FIG. 7C is a schematic diagram illustrating a deformation of the supporting member when the sample holding member is driven in the focus direction according to the first embodiment, and is a diagram illustrating the sample holding member displaced in the focus direction while being inclined to the plane perpendicular to the focus direction.

FIG. 8 is a diagram illustrating the sample holding member, the supporting member, the sample drive unit, and a rotation drive unit of the surface inspecting device according to a second embodiment of the present invention.

FIG. 9A is a diagram illustrating a configuration of the supporting member according to the second embodiment.

FIG. 9B is a diagram illustrating the supporting member including, as a first supporting member, an annular thin plate that s divided into a plurality of parts in a circumferential direction according to the second embodiment.

FIG. 10 is a top view illustrating a supporting member fixed to the rotation drive unit according to the second embodiment.

FIG. 11A is a schematic diagram illustrating a deformation of the supporting member when the sample holding member is driven in the focus direction according to the second embodiment, and is a diagram illustrating the sample holding member in non-displaced state.

FIG. 11B is a schematic diagram illustrating a deformation of the supporting member when the sample holding member is driven in the focus direction according to the second embodiment, and is a diagram illustrating the sample holding member displaced in the focus direction without being inclined to the plane perpendicular to the focus direction.

FIG. 11C is a schematic diagram illustrating a deformation of the supporting member when the sample holding member is driven in the focus direction according to the second embodiment, and is a diagram illustrating the sample holding member displaced in the focus direction while being inclined to the plane perpendicular to the focus direction.

FIG. 12 is a diagram illustrating a part of the supporting member according to the second embodiment, and is a diagram illustrating a portion of the thin plate and some of a plurality of block members.

### DESCRIPTION OF EMBODIMENTS

A surface inspecting device according to the present invention can accurately and rapidly drive a sample in a focus direction (height direction or up-and-down direction) while rotating the sample, while keeping the inclination of the sample small. Therefore, the surface inspecting device according to the present invention can keep a position of a surface of the sample within an acceptable focus range of an optical system, enabling accurate inspection of the sample.

Hereinafter, the surface inspecting device according to an embodiment of the present invention will be described with reference to the drawings. In the drawings used for the description, the same or corresponding components are denoted by the same reference numerals, and repeated description of these components may be omitted.

### First Embodiment

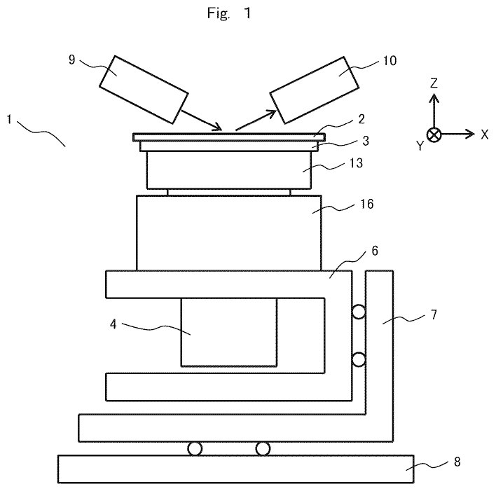

FIG. 1 is a diagram illustrating a configuration of a surface inspecting device 1 according to a first embodiment of the present invention. The surface inspecting device 1 includes a sample holding member 3, a spindle motor 4, a frame 6, a vertical driving stage 7, a horizontal driving stage 8, an illumination optical system 9, a detection optical system 10, a yoke 13, and a coil fixing member 16.

The sample holding member 3 is plate-shaped (e.g., disk-shaped) and can hold a sample 2. The sample 2 is, for example, a plate-shaped wafer. Hereinafter, aspects will be described based on the assumption that the sample holding member 3 has a disk shape and that the sample 2 has a disk shape.

In FIG. 1, the height direction (up-and-down directions of FIG. 1) of the surface inspecting device 1 is referred to as a focus direction or a Z direction, and two directions (horizontal directions) perpendicular to the focus direction are referred to as an X direction and a Y direction. In addition, virtual axes parallel to the X direction, the Y direction and the Z direction are referred to as the X-axis, the Y-axis and the Z-axis, respectively.

The spindle motor 4 is a motor for rotating the sample 2 and the sample holding member 3 around the Z-axis.

The spindle motor 4 is fixed to the frame 6.

The vertical driving stage 7 moves the frame 6 in the focus direction (the Z direction) so that a position of a surface of the sample 2 is within a predetermined height range. The vertical driving stage 7 moves the frame 6 to move the sample 2 and the sample holding member 3 in the focus direction.

The horizontal driving stage 8 moves the vertical driving stage 7 and the frame 6 in a radial direction of the sample holding member 3 (the X direction in FIG. 1). The horizontal driving stage 8 moves the vertical driving stage 7 and the frame 6 to move the sample holding member 3 and the sample 2 in the radial direction of the sample holding member 3.

The illumination optical system 9 irradiates the surface of the sample 2 with a laser light beam. The laser light irradiated on the surface of the sample 2 is scattered by foreign substances or defects on the surface of the sample 2 to become scattered light.

The detection optical system 10 receives the scattered light generated on the surface of the sample 2. A processing device (not illustrated) is connected to the detection optical system 10. The processing device detects the presence or absence of foreign substances or defect on the surface of the sample 2 from a signal of the scattered light received by the detection optical system 10, and identifies the position of the foreign substances or defect based on the rotation angle of the sample holding member 3 and the position thereof in the radial direction (X direction).

The coil fixing member 16 is fixed to the frame 6.

The yoke 13 is a cylindrical member. The yoke 13 will be described below.

The surface inspecting device 1 according to the present embodiment further includes a turntable. The turntable will be described below.

The surface inspecting device 1 scans the entire surface of the sample 2 with a laser light beam from the illumination optical system 9 by moving the sample holding member 3 in the radial direction (the X direction) of the sample holding member 3 using the horizontal driving stage 8 while rotating the sample holding member 3 around the Z axis using the spindle motor 4.

The vertical driving stage 7 is a mechanism for adjusting the average height position (position in the focus direction) of the surface of the sample 2. The speed at which the vertical driving stage 7 moves the frame 6 in the focus direction, that is, the speed at which the sample holding member 3 is moved in the focus direction by the vertical driving stage 7, is slower than the speed (rotation frequency) of rotation of the sample holding member 3 by the spindle motor 4.

In order to inspect the sample 2 with high accuracy, it is required that the height position of the sample holding member 3 (i.e., the surface of the sample 2) be adjusted following the positional change of the sample holding member 3 in the focus direction during rotation of the sample holding member 3 holding the sample 2.

The surface inspecting device 1 according to the present embodiment includes a sample drive unit capable of adjusting the height position of the sample holding member 3 (the surface of the sample 2) in response to the positional change in the focus direction during rotation of the sample holding member 3, and a plurality of supporting members supporting the sample holding member 3 in a manner allowing displacement in the focus direction.

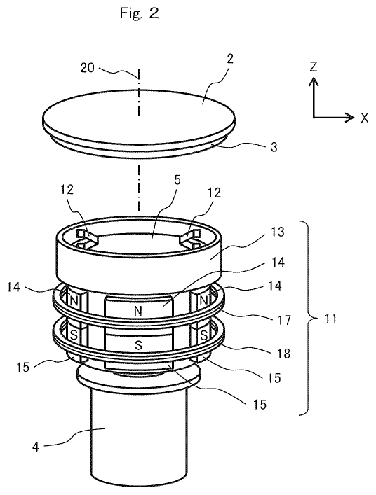

FIG. 2 is a diagram illustrating a sample drive unit 11 of the surface inspecting device 1 according to the present embodiment, a plurality of supporting members 12, and surrounding components (the sample holding member 3 holding the sample 2 and the spindle motor 4). In FIG. 2, for ease of understanding, the illustrations of the frame 6, the vertical driving stage 7, the horizontal driving stage 8, and the coil fixing member 16 are omitted, and the sample holding member 3 separated from the sample drive unit 11 is illustrated.

FIG. 2 illustrates a central axis 20 of the sample holding member 3. The central axis 20 of the sample holding member 3 is parallel to the focus direction (the Z direction). The sample holding member 3 is rotated around the central axis 20 by the action of the spindle motor 4.

The surface inspecting device 1 includes a turntable 5 provided on the spindle motor 4. The turntable 5 is fixed to one end of the spindle motor 4 and rotated around the Z-axis by the action of the spindle motor 4 to rotate the sample 2 and the sample holding member 3 around the Z-axis. The turntable 5 is positioned inside a cylindrical yoke 13.

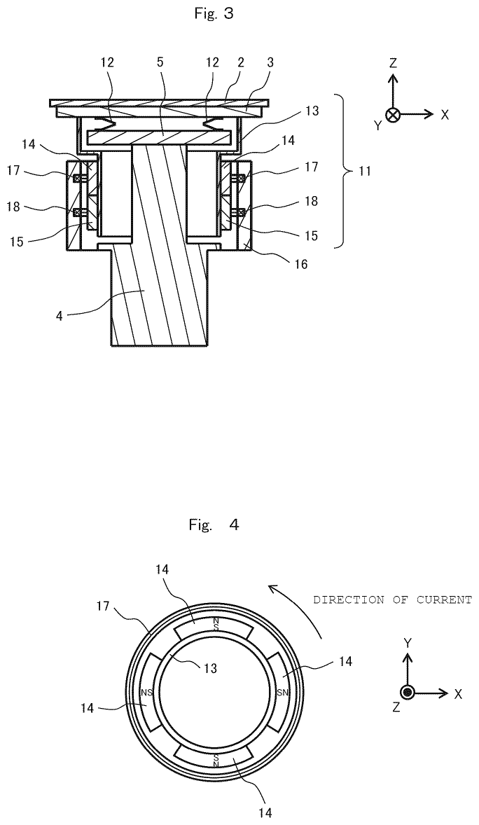

FIG. 3 is a cross-sectional view in the XZ plane showing the sample drive unit 11, the plurality of supporting members 12, and the surrounding components. In FIG. 3, the illustrations of the frame 6, the vertical driving stage 7, and the horizontal driving stage 8 are omitted.

The sample drive unit 11 and the supporting members 12 are described with reference to FIGS. 2 and 3.

The sample drive unit 11 includes the yoke 13, a plurality of first magnets 14, a plurality of second magnets 15, a first coil 17, and a second coil 18. The sample drive unit 11 can displace the sample holding member 3 in the focus direction (the Z direction) with respect to the turntable 5.

The yoke 13 includes a cylindrical part with the focus direction (the Z direction) as a central axis, and has the sample holding member 3 fixed to an upper portion thereof. In FIGS. 2 and 3, as an example, the yoke 13 including two cylindrical parts with different radial lengths from the sample holding member 3 is illustrated.

The plurality of first magnets 14 are provided on an outer surface of the cylindrical part of the yoke 13 at a first height position in the focus direction. The plurality of first magnets 14 are fixed to a surface of the yoke 13 at intervals along a circumferential direction of the yoke 13.

The plurality of second magnets 15 are provided on the outer surface of the cylindrical part of the yoke 13 at a second height position in the focus direction. The plurality of second magnets 15 are fixed to the surface of the yoke 13 at intervals along the circumferential direction of the yoke 13. The second height position differs from the first height position in the focus direction (height direction).

In addition, the number of the plurality of first magnets 14 is preferably equal to the number of the plurality of second magnets 15.

The first coil 17 has an annular shape, and is fixed to the coil fixing member 16 (FIG. 3) and disposed around the first magnet 14.

The second coil 18 has an annular shape, and is fixed to the coil fixing member 16 and disposed around the second magnet 15.

The plurality of supporting members 12 are provided between the sample holding member 3 and the turntable 5. Each of the supporting members 12 has one end portion fixed to the sample holding member 3, and the other end portion fixed to the turntable 5. The plurality of supporting members 12 are members that support the sample 2 and the sample holding member 3 in a manner allowing displacement in the focus direction (the Z direction) with respect to the turntable 5, and are members for suppressing the inclination of the sample holding member 3 and the sample 2. The supporting members 12 can be configured with, for example, an elastic member such as a spring. The supporting members 12 configured with the elastic member have the advantage of excellent linearity of operation and less wear due to not utilizing friction forces.

Although FIGS. 2 and 3 illustrate the supporting members 12 having one bent portion, the shape of the supporting members 12 can be arbitrarily determined. For example, the supporting members 12 may have a shape having a plurality of bent portions or may have a curved shape.

As illustrated in FIGS. 1 to 3, the spindle motor 4 is fixed to the turntable 5, the turntable 5 is fixed to the supporting members 12, and the supporting members 12 are fixed to the sample holding member 3. Therefore, when the spindle motor 4 is rotated, the turntable 5 is rotated around the Z-axis, and as the turntable 5 is rotated, the sample holding member 3 is rotated around the Z-axis via the supporting members 12. The sample 2 held by the sample holding member 3 is rotated around the Z axis in this way by the action of the spindle motor 4.

FIG. 4 is a diagram illustrating an arrangement of the first magnets 14 provided on the yoke 13 and the first coil 17. FIG. 4 illustrates a cross section (XY plane) perpendicular to the focus direction of the sample drive unit 11 at a height position (the first height position in the focus direction) where the first magnet 14 is provided.

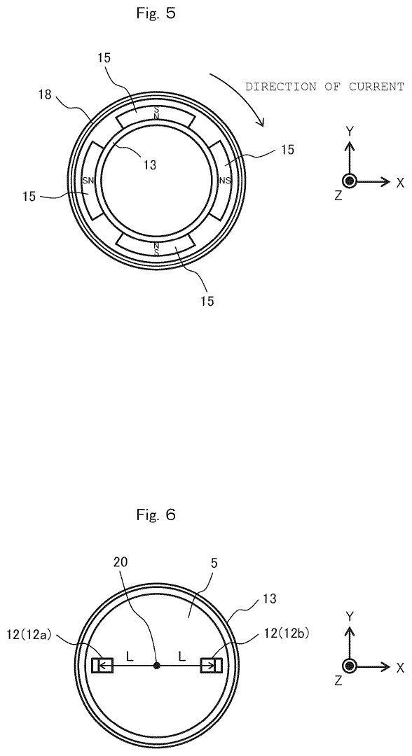

FIG. 5 is a diagram illustrating an arrangement of the second magnets 15 provided on the yoke 13 and the second coil 18. FIG. 5 illustrates a cross section (XY plane) perpendicular to the focus direction of the sample drive unit 11 at a height position (the second height position in the focus direction) where the second magnet 15 is provided.

The first magnet 14 and the second magnet 15 have an arc shape when viewed from the focus direction (the Z direction) and are provided on the outer surface of the cylindrical part of the yoke 13.

The first magnet 14 is magnetized in the radial direction of the sample holding member 3, with a surface opposite to the surface in contact with the yoke 13 having a first polarity (N pole in this embodiment), and the surface in contact with the yoke 13 having a second polarity (S pole in this embodiment).

The second magnet 15 is magnetized in the radial direction of the sample holding member 3, with a surface opposite to the surface in contact with the yoke 13 having a second polarity (S pole in this embodiment), and the surface in contact with the yoke 13 having a first polarity (N pole in this embodiment). That is, the second magnet 15 has a polarity opposite to that of the first magnet 14.

When the sample drive unit 11 displaces the sample holding member 3 in the focus direction, a current opposite to a current flowing in the second coil 18 flows in the first coil 17 when viewed from the focus direction (the Z direction).

As illustrated in FIG. 4, when a current flows counterclockwise through the first coil 17 when viewed from the upper side of the focus direction, a downward force in the focus direction (negative Z direction) acts on the first coil 17 and an upward force in the focus direction (positive Z direction) acts on the first magnets 14 by interaction with the magnetic field from the first magnet 14.

As illustrated in FIG. 5, when a current flows clockwise through the second coil 18 when viewed from the upper side of the focus direction, a downward force in the focus direction (negative Z direction) acts on the second coil 18 and an upward force in the focus direction (positive Z direction) acts on the second magnets 15 by interaction with the magnetic field from the second magnet 15.

By the force acting on the first magnets 14 and the second magnets 15, the first magnets 14 and the second magnets 15 are displaced upward in the focus direction. Along with the displacement of the first magnets 14 and the second magnets 15, the yoke 13 and the sample holding member 3 are also displaced upward in the focus direction.

Meanwhile, the first coil 17 and the second coil 18 are fixed to the spindle motor 4 through the coil fixing member 16 and the frame 6, and the spindle motor 4 is fixed to the turntable 5. Therefore, the turntable 5 is not displaced in the focus direction even when the sample holding member 3 is displaced in the focus direction.

That is, the first magnets 14, the second magnets 15, the yoke 13, and the sample holding member 3 are movable parts that are displaced in the focus direction, while the first coil 17, the second coil 18, and the turntable 5 are fixed parts that are not displaced in the focus direction.

Accordingly, when the sample holding member 3 is displaced upward in the focus direction, the supporting members 12 having both end portions fixed to the sample holding member 3 and the turntable 5 are stretched in the focus direction because the turntable 5 is not displaced. When the direction of the current flowing through the first coil 17 and the second coil 18 is reversed from the direction described above (clockwise in FIG. 4 and counterclockwise in FIG. 5), the sample holding member 3 is displaced downward in the focus direction, and the supporting members 12 are contracted in the focus direction.

The sample 2 held by the sample holding member 3 is displaced in the focus direction by the displacement of the sample holding member 3.

The orientation of the polarity of the first magnet 14 and the second magnet 15 may be opposite to the example described above. When orientation of the polarities of the first magnets 14 and the second magnet 15 are reversed from the example described above, the relationship between the direction of current flowing through the first coil 17 and the second coil 18 and a direction of displacement of the sample holding member 3 in the focus direction is reversed from the example described above.

As described above, in the surface inspecting device 1 according to the present embodiment, the movable parts are displaced in the focus direction by currents flowing through the first coil 17 and the second coil 18, and the supporting members 12 are stretched and contracted in accordance with the displacement of the movable part so that the sample holding member 3 and the sample 2 can be driven in the focus direction by the sample drive unit 11. Driving the sample holding member 3 and the sample 2 in the focus direction by the sample drive unit 11 can also be performed while the spindle motor 4 is rotated. That is, in the surface inspecting device 1 according to the present embodiment, the sample holding member 3 and the sample 2 can be driven in the focus direction by the sample drive unit 11 while being rotated by the spindle motor 4.

When the plurality of supporting members 12 are not installed in positions that are balanced with respect to the sample holding member 3, or the elastic forces of the plurality of supporting members 12 are not balanced, there is a possibility that the plurality of supporting members 12 will support the sample holding member 3 and the sample 2 in the inclined state. Hereinafter, the arrangement of the supporting members 12 and the inclination of the sample holding member 3 (the inclination to the direction perpendicular to the focus direction) in relation to the deformation of the supporting members 12 will be described.

FIG. 6 is a top view illustrating the arrangement of the sample holding member 3 and the supporting members 12 in the turntable 5. In FIG. 6, only the turntable 5, the supporting members 12, and the yoke 13 are shown to clearly illustrate the arrangement of the supporting members 12. FIG. 6 shows that two supporting members 12 are provided as an example.

The two supporting members 12 are arranged at equal intervals in the circumferential direction on a circumference of the sample holding member 3 (and the turntable 5) equidistance from the central axis 20 of the sample holding member 3. Specifically, the two supporting members 12 are arranged on the circumference of a circle with a radius L centered on the central axis 20 of the sample holding member 3, at positions that divide this circumference into two equal parts (positions where the center angle is 180 degrees). More specifically, the positions of the connection points between the two supporting members 12 and the sample holding member 3 are on the circumference of the circle with the radius L centered on the central axis 20, at positions that divide this circumference into two equal parts.

By arranging the supporting members 12 at equal intervals in the circumferential direction on the circumference equidistance from the central axis 20 of the sample holding member 3, the positions of the connection points between the supporting members 12 and the sample holding member 3 become symmetrical with respect to the central axis 20, thus reducing the impact of variations in the positions of the connection points between the supporting members 12 and the sample holding member 3.

The supporting members 12 are preferably installed at positions relative to the sample holding member 3 such that a distance L from the central axis 20 of the sample holding member 3 is at least half the radius R of the sample holding member 3. More specifically, the supporting members 12 are preferably installed at positions of the sample holding member 3 where the distance L from the central axis 20 of the sample holding member 3 to the connection point between the supporting member 12 and the sample holding member 3 is at least half the radius R of the sample holding member 3. When the supporting members 12 are installed at such positions (positions where L≥R/2), there is an effect that the inclination of the sample holding member 3 and the sample 2 is suppressed when the sample holding member 3 is driven in the focus direction. This will be described below.

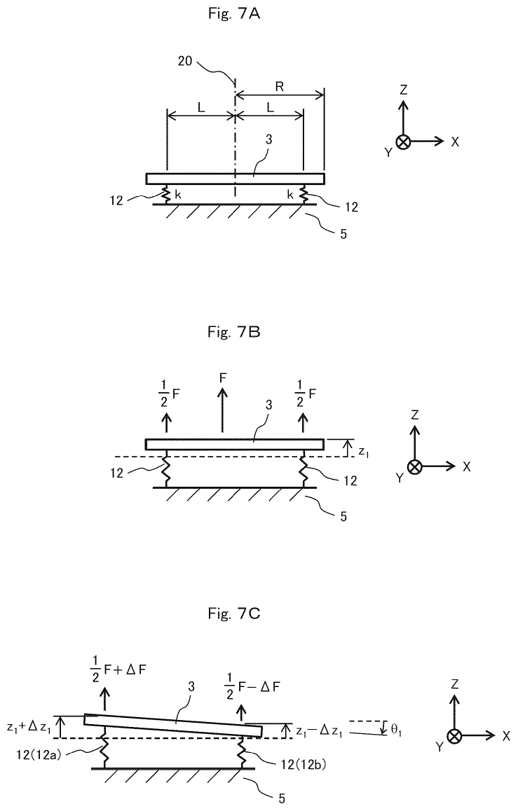

FIGS. 7A, 7B, and 7C are schematic diagrams illustrating a deformation of the supporting members 12 when the sample holding member 3 is driven in the focus direction, and are diagrams illustrating the sample holding member 3 and the supporting members 12 when viewed from the Y direction. In FIGS. 7A, 7B, and 7C, for simplification, the movable part is represented by the sample holding member 3, and the fixed part is represented by the turntable 5. FIG. 7A is a diagram illustrating the sample holding member 3 in a non-displaced state. FIG. 7B illustrates the sample holding member 3 displaced in the focus direction without being inclined to the plane (XY plane) perpendicular to the focus direction. FIG. 7C is a diagram illustrating the sample holding member 3 displaced in the focus direction while being inclined to the plane perpendicular to the focus direction.

As illustrated in FIG. 7A, the supporting members 12 are configured with springs having a spring constant of k. In addition, FIG. 7A shows, within the plane of the sample holding member 3, the distance L from the central axis 20 of the sample holding member 3 to the position of the connection point between the supporting member 12 and the sample holding member 3, and the radius R of the sample holding member 3.

As illustrated in FIG. 7B, it is assumed that F is the total driving force in the focus direction acting on the movable part represented by the sample holding member 3, F/2 is the driving force acting on each supporting members 12, and z₁ is the displacement of the movable part in the focus direction. When the mass of the movable part is m, and the resonance frequency of the translational mode, which is a mode in which the sample holding member 3 is moved in the focus direction without being inclined, is f_{z1}, the following equations may be expressed:

$$\begin{matrix}[ Equation l ] & \\ F = 2 {kz}_{1} & ( 1 )\end{matrix}$$

$$\begin{matrix}[ Equation 2 ] & \\ {f}_{z 1} = \frac{1}{2 π} \sqrt{\frac{2 k}{m}} & ( 2 )\end{matrix}$$

FIG. 7C illustrates an example in which the driving force acting on one supporting member 12 (12a) increases by ΔF, while the driving force acting on the other supporting member 12 (12b) decreases by ΔF. It is assumed that the displacement of the supporting members 12a is z₁+Δ_{z1}, the displacement of the supporting members 12b is z₁−Δ_{z1}, and the inclination of the sample holding member 3 around the Y-axis is θ₁. Assuming that θ₁ is very small, the following equation may be expressed:

$$\begin{matrix}[ Equation 3 ] & \\ {θ}_{1} = \frac{Δ {z}_{1}}{L} & ( 3 )\end{matrix}$$

A stiffness k_{θ1} of the supporting members 12 against this inclination of the sample holding member 3 may be:

k_{θ1}=2kL² (4)[Equation 4]

When it is assumed that I is the moment of inertia of the movable part around the Y-axis, and f_{θ1} is the resonance frequency of the inclination mode in which the sample holding member 3 is inclined around the Y-axis, the resonance frequency f_{θ1} of the inclination mode is expressed as follows:

$$\begin{matrix}[ Equation 5 ] & \\ {f}_{{θ}_{1}} = \frac{1}{2 π} \sqrt{\frac{2 {kL}^{2}}{I}} & ( 5 )\end{matrix}$$

The inclination mode refers to a mode in which the sample holding member 3 is inclined with respect to the plane (horizontal plane) perpendicular to the focus direction.

When it is assumed that the sample holding member 3 is a thin disk, the moment of inertia I is:

$$\begin{matrix}[ Equation 6 ] & \\ I = \frac{{mR}^{2}}{4} & ( 6 )\end{matrix}$$

From Equations (2), (5), and (6), the following expression representing the resonance frequency f_{θ1} in the inclination mode is obtained:

$$\begin{matrix}[ Equation 7 ] & \\ {f}_{{θ}_{1}} = \frac{2 L}{R} {f}_{{z}_{1}} & ( 7 )\end{matrix}$$

From Equation (4), the stiffness k_{θ1} of the supporting members 12 against the inclination of the sample holding member 3 is proportional to the square of the distance L from the central axis 20 of the sample holding member 3 to the position of the connection point between the supporting member 12 and the sample holding member 3. Therefore, the larger the distance L, that is, the more the attachment position of the supporting members 12 to the sample holding member 3 towards the outer circumference of the sample holding member 3, the greater the stiffness k_{θ1} of the supporting members 12, and the smaller the inclination θ₁ of the sample holding member 3 can be made.

In particular, from Equation (7), by making the distance L to at least half the radius R of the sample holding member 3, the resonance frequency for of the inclination mode can be made equal to or greater than the resonance frequency f_{z1} of the translational mode (i.e., when L≥R/2, then f_{θ1}≥f_{z1}). When the resonance frequency f_{θ1} of the inclination mode is made equal to or greater than the resonance frequency f_{z1} of the translational mode, the inclination of the sample holding member 3 caused by the influence of resonance in the inclination mode can be suppressed when the sample holding member 3 is driven in the focus direction.

The reason for this will be described below. In general, in the surface inspecting device, driving the sample holding member 3 and the sample 2 in the focus direction is performed at the resonance frequency f_{z1} of the translational mode or less. When the resonance frequency f_{θ1} of the inclination mode is less than the resonance frequency f_{z1} of the translational mode, there is a possibility that the resonance frequency f_{θ1} of the inclination mode becomes a value close to the driving frequency of the sample holding member 3 in the focus direction, increasing the inclination of the sample holding member 3.

The distance L is set to be at least half the radius R of the sample holding member 3 (L≥R/2), the stiffness k_{θ1} of the supporting members 12 against the inclination of the sample holding member 3 is increased, and the resonance frequency f_{θ1} of the inclination mode is set to be equal to or greater than the resonance frequency f_{z1} of the translational mode (f_{θ1}≥f_{z1}). When f_{θ1}2f_{z1}, the resonance frequency f_{θ1} of the inclination mode can be set to a value far from the driving frequency of the sample holding member 3 in the focus direction, thus suppressing the inclination of the sample holding member 3. In the surface inspecting device 1 according to the present embodiment, by setting L≥R/2 to make f_{θ1}≥f_{z1}, the inclination (inclination relative to the horizontal direction) of the sample holding member 3 caused by the influence of the resonance of the inclination mode can be suppressed when the sample holding member 3 and the sample 2 are driven in the focus direction.

Meanwhile, when the elastic modulus of the supporting members 12 is simply increased to increase the stiffness k_{θ1} of the supporting members 12 against the inclination of the sample holding member 3, the stiffness in the focus direction also increases and the amount of displacement of the sample holding member 3 in the focus direction decreases. In the surface inspecting device 1 according to the present embodiment, when the supporting members 12 is installed at a position where L≥R/2, it is possible to increase the stiffness k_{θ1} against the inclination of the sample holding member 3 while suppressing the magnitude of stiffness in the focus direction.

In addition, the surface inspecting device 1 according to the present embodiment, the first magnet 14 and the second magnet 15 are preferably arranged in contact with each other in the focus direction. When only the first magnets 14 are installed on the yoke 13 or only the second magnets 15 are installed on the yoke 13, the magnets of the same polarity are arranged in the circumferential direction of the yoke 13 and these magnets repel each other, making the installation of the magnets on the yoke 13 unstable. On the other hand, when the first magnets 14 and the second magnets 15 having different polarities are arranged in contact with each other in the focus direction, the first magnets 14 and the second magnets 15 form a magnetic circuit, allowing for a stable installation of the first magnets 14 and the second magnets 15 on the yoke 13.

It is to be noted that while the present embodiment illustrates that the number of first magnets 14 and the number of second magnets 15 are four, respectively, the number of the first magnets 14 and the second magnets 15 is not limited to four and can be arbitrarily determined.

The surface inspecting device 1 according to the present embodiment is able to, in addition to moving the sample holding member 3 and the sample 2 in the focus direction by the vertical driving stage 7, drive the sample holding member 3 and the sample 2 in the focus direction by the sample drive unit 11 at a higher speed than movement in the focus direction by the vertical driving stage 7, while rotating the sample holding member 3 and the sample 2 around the Z axis with the spindle motor 4. A related surface inspecting device moves the sample holding member 3 and the sample 2 in the focus direction by the vertical driving stage 7 at a speed slower than the rotational speed of the sample holding member 3. Furthermore, the surface inspecting device 1 according to the present embodiment further includes the plurality of supporting members 12 and the sample drive unit 11 and accordingly, is able to drive the sample holding member 3 in the focus direction accurately and at high speed, following the positional change in the focus direction during the rotation of the sample holding member 3, and to allow adjustment of the height position of the surface of the sample 2.

The surface inspecting device 1 according to the present embodiment can reduce the influence of variation in the position of the connection points between the supporting members 12 and the sample holding member 3, and increase stiffness of the supporting members 12 against the inclination of the sample holding member 3, and additionally, due to the good installation stability of the first magnets 14 and the second magnets 15, it is possible to suppress variations in the driving force produced by the magnets. Therefore, the surface inspecting device 1 according to the present embodiment can keep the influence of inclination of the sample holding member 3 and the sample 2 small, drive the sample holding member 3 accurately in the focus direction, and thus accurately inspect the sample 2.

### Second Embodiment

A surface inspecting device 1 according to a second embodiment of the present invention will be described. In the surface inspecting device 1 according to the present embodiment, the structure of the supporting member is different from that of the surface inspecting device 1 according to the first embodiment, while other configurations are the same as those of the surface inspecting device 1 according to the first embodiment. Hereinafter, the surface inspecting device 1 according to the present embodiment is mainly described in terms of the differences from the surface inspecting device 1 according to the first embodiment. The surface inspecting device 1 according first embodiment includes the plurality of supporting members 12 (FIG. 2), but the surface inspecting device 1 according to the present embodiment includes one supporting member.

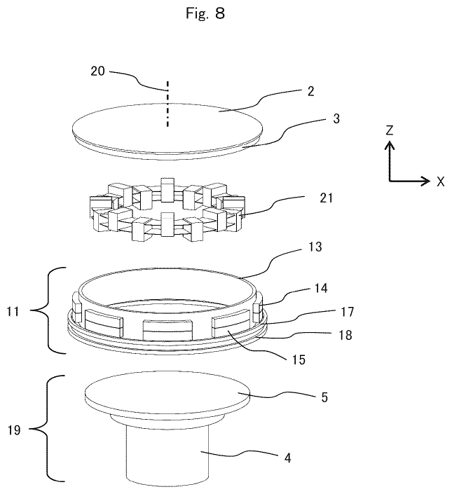

FIG. 8 is a diagram illustrating a sample holding member 3, a supporting member 21, a sample drive unit 11, and a rotation drive unit 19 of the surface inspecting device 1 according to the present embodiment. The sample holding member 3 holds a sample 2. In FIG. 8, for ease of understanding, the illustrations of a frame 6, a vertical driving stage 7, a horizontal driving stage 8, and a coil fixing member 16 are omitted, and the sample holding member 3, the supporting member 21, the sample drive unit 11 and the rotation drive unit 19 separated from each other are illustrated.

The rotation drive unit 19 includes a spindle motor 4 and a turntable 5, and rotates the sample 2 and the sample holding member 3 around the Z-axis. The rotation drive unit 19 may not include the turntable 5.

The sample drive unit 11 can displace the sample holding member 3 in the focus direction (the Z direction) with respect to the rotation drive unit 19.

The supporting member 21 is provided between the sample holding member 3 and the rotation drive unit 19, and is fixed to the sample holding member 3 and the rotation drive unit 19. The supporting member 21 is a member that supports the sample 2 and the sample holding member 3 in a manner allowing displacement in the focus direction (the Z direction) with respect to the rotation drive unit 19, and is a member for suppressing the inclination of the sample holding member 3 and the sample 2.

When the rotation drive unit 19 has a configuration including the turntable 5, the supporting member 21 is fixed to the turntable 5. When the rotation drive unit 19 has a configuration without the turntable 5, the supporting member 21 is fixed to the spindle motor 4.

FIG. 8 illustrates the central axis 20 of the sample holding member 3.

Hereinafter, the direction around the focus direction (the Z direction) is referred to as a circumferential direction.

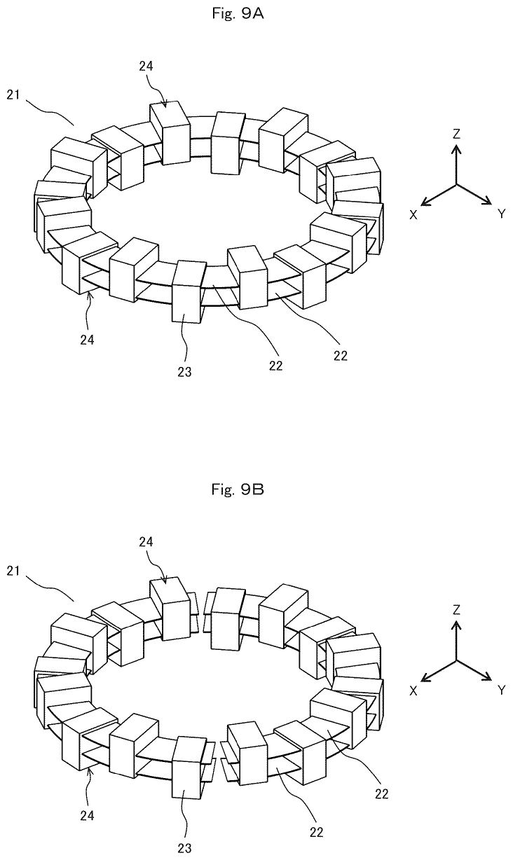

Referring to FIGS. 9A and 9B, the supporting member 21 will be described.

FIG. 9A is a diagram illustrating a configuration of the supporting member 21. The supporting member 21 includes a first supporting member and a plurality of second supporting members. The second supporting members support the first supporting member.

The first supporting member is a plate-shaped member disposed around the central axis 20 (FIG. 8) of the sample holding member 3 and is configured with one or a plurality of thin plates 22. In FIG. 9A, as an example, the supporting member 21 having two thin plates 22 as the first supporting member is illustrated, and the two thin plates 22 form a closed annular shape in the circumferential direction. The first supporting member is supported by the plurality of second supporting members and is positioned between the sample holding member 3 and the rotation drive unit 19, and is displaceable in the height direction (the focus direction) relative to the sample holding member 3 and the rotation drive unit 19.

The thin plate 22 is a plate-shaped member configured with metal such as stainless steel, for example, and is an elastic member that extends in the circumferential direction. The thin plate 22 has its plate surface facing the sample holding member 3 (FIG. 8), and has a thin thickness in the focus direction. The shape of the thin plate 22 can be arbitrarily determined. For example, the thin plate 22 may be in the shape of a circular ring or a polygonal ring. Further, the thin plate 22 may be in the shape of a ring open in the circumferential direction or in the shape of a ring divided into a plurality of parts in the circumferential direction. Further, the thin plate 22 may be a plate-shaped member curved in the focus direction rather than a flat plate.

FIG. 9B is a diagram illustrating the supporting member 21 including, as the first supporting member, an annular thin plate that is divided into a plurality of parts in the circumferential direction. In the example illustrated in FIG. 9B, both of the two thin plates 22 have an annular shape and is divided into two parts in the circumferential direction.

The thin plate 22 is a member for absorbing and suppressing the inclination of the sample holding member 3, and is preferably a member that is flexible (i.e., has low bending stiffness) while having a high tensile and compressive stiffness. With a low bending stiffness and a high tensile and compressive stiffness, the thin plate 22 can effectively suppress the inclination of the sample holding member 3.

When the first supporting member is configured with the plurality of thin plates 22, the number of thin plates 22 can be arbitrarily determined. The plurality of thin plates 22 are arranged side by side in the focus direction. The plurality of thin plates 22 may or may not be parallel to each other. However, the thin plates 22 are preferably arranged such that when the sample holding member 3 is inclined, the tensile and compressive components of the forces applied to the thin plate 22 become larger. When the plurality of thin plates 22 are not parallel to each other, as the sample holding member 3 is inclined, the ratio of the bending component among the components of the force applied to the thin plate becomes relatively larger (compared to when the plurality of thin plates 22 are parallel), and the ratio of the tensile and compressive components becomes smaller. Therefore, the effect of suppressing the inclination of the sample holding member 3 may be lower than when the plurality of thin plates 22 are parallel to each other. Therefore, the plurality of thin plates 22 are preferably parallel to each other.

As illustrated in FIGS. 9A and 9B, the first supporting member is further preferably configured with two thin plates 22 parallel to each other. According to the numerical simulation analysis result, when the first supporting member is configured with two thin plates 22 parallel to each other, it is possible to effectively make the resistance to tension and compression (tensile and compressive stiffness) of the first supporting member greater than the resistance to bending (bending stiffness) when the sample holding member 3 is driven in the focus direction. Further, since the tensile and compressive forces are more effectively applied to the thin plate 22 when the sample holding member 3 is inclined (i.e., the force is not lost through bending), the inclination of the sample holding member 3 can be efficiently suppressed.

Each of the plurality of second supporting members is configured with a block member 23 supporting the first supporting member. The plurality of second supporting members are arranged in an annular shape around the central axis 20 of the sample holding member 3.

The block member 23 is, for example, a solid member configured with metal and supports the thin plate 22. The shape of the block member 23 can be arbitrarily determined, with a rectangular parallelepiped being preferable, for example. The number of the block members 23 can be determined arbitrarily. FIGS. 9A and 9B illustrate a configuration in which the second supporting member includes 16 block members 23 as an example. A plurality of block members 23 are preferably arranged along the first supporting member (the thin plate 22) and arranged at equal intervals in the circumferential direction. When the first supporting member is configured with the plurality of thin plates 22, the block member 23 maintains the interval between the thin plates 22 in the focus direction.

Some of the plurality of block members 23 are fixed to the sample holding member 3, and the remainder are fixed to the rotation drive unit 19. One block member 23 is fixed to only one of the sample holding member 3 and the rotation drive unit 19. The part of the block member 23 that is fixed to the sample holding member 3 or the rotation drive unit 19 is referred to as a fixed part 24.

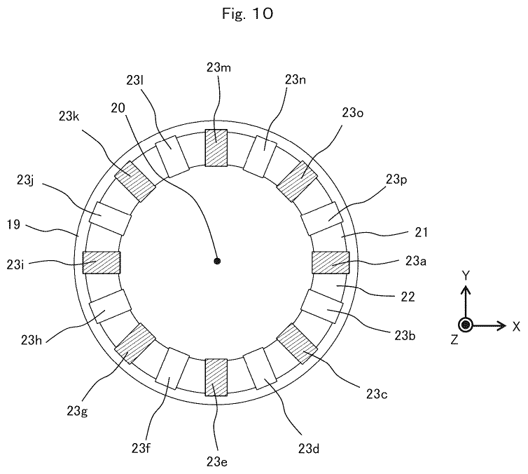

FIG. 10 is a top view illustrating the supporting member 21 fixed to the rotation drive unit 19. The supporting member 21 includes the first supporting member, that is, the thin plate 22, and a plurality of second supporting members, that is, a plurality of block members 23. FIG. 10 illustrates 16 block members 23 (23a through 23p), similar to FIGS. 9A and 9B.

The supporting member 21 is preferably disposed equidistance from the central axis 20, around the central axis 20 of the sample holding member 3. In other words, in the radial direction of the sample holding member 3 (direction within the XY plane), the supporting member 21 is preferably disposed so that the center of the supporting member 21, more specifically, the center of the thin plate 22 is positioned equidistance from the central axis 20.

The plurality of block members 23 are alternately fixed to the sample holding member 3 and the rotation drive unit 19 along the circumferential direction. In the present embodiment, the plurality of block members 23 are alternately fixed one by one to the sample holding member 3 and the rotation drive unit 19 along the circumferential direction. That is, among the 16 block members 23, 8 block members 23a, 23c, 23e, 23g, 231, 23k, 23m, and 230 are fixed to the sample holding member 3, and the remaining 8 block members 23b, 23d, 23f, 23h, 23j, 231, 23n, and 23p are fixed to the rotation drive unit 19. The plurality of block members 23 may be fixed to the sample holding member 3 and the rotation drive unit 19 alternately in plural numbers (for example, alternating in groups of two) along the circumferential direction.

When the plurality of block members 23 are alternately fixed to the sample holding member 3 and the rotation drive unit 19 along the circumferential direction, the effect of making the thin plate 22 bend easily and increasing the tensile and compressive stiffness, that is, the effect of suppressing the inclination of the sample holding member 3, becomes greater. As in the present embodiment, when the plurality of block members 23 are alternately fixed one by one to the sample holding member 3 and the rotation drive unit 19 along the circumferential direction, this effect can be further increased.

As described above, the plurality of block members 23 are fixed to the sample holding member 3 or the rotation drive unit 19. The fixed part 24 of the block member 23 to the sample holding member 3 or the rotation drive unit 19 is preferably a plane. When the fixed part 24 is a plane, the effect of suppressing the inclination of the sample holding member 3 by bending (flexing) the thin plate 22 can be increased.

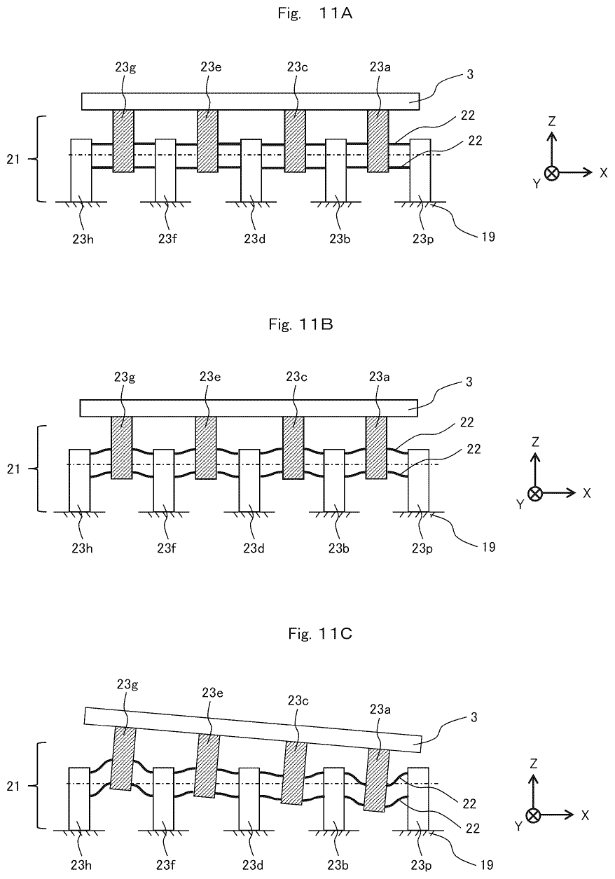

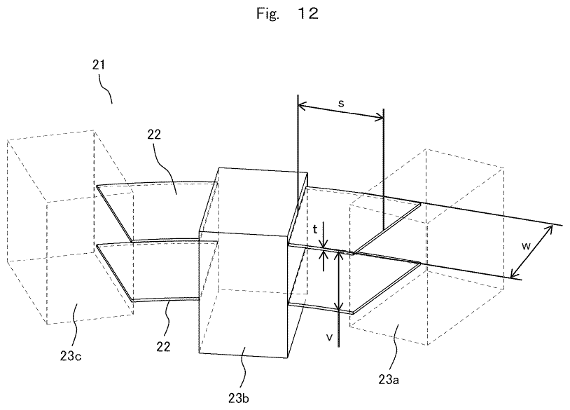

FIGS. 11A, 11B, and 11C are schematic diagrams illustrating a deformation of the supporting member 21 when the sample holding member 3 is driven in the focus direction, and are diagrams illustrating the sample holding member 3 and the supporting member 21 when viewed from the Y direction. In FIGS. 11A, 11B, and 11C, for simplification, the movable part is represented by the sample holding member 3, and the fixed part is represented by the rotation drive unit 19. FIGS. 11A, 11B, and 11C also illustrate the block members 23a, 23c, 23e, and 23g fixed to the sample holding member 3, and the block members 23p, 23b, 23d, 23f, and 23h fixed to the rotation drive unit 19, among the block members 23 of the supporting member 21.

FIG. 11A is a diagram illustrating the sample holding member 3 in a non-displaced state. FIG. 11B is a diagram illustrating the sample holding member 3 displaced in the focus direction without being inclined to the plane (XY plane) perpendicular to the focus direction. FIG. 11C is a diagram illustrating the sample holding member 3 displaced in the focus direction while being inclined to the plane perpendicular to the focus direction. In FIG. 11C, the sample holding member 3 is inclined around the Y-axis.

As illustrated in FIG. 11A, no bending force or tensile and compressive force is applied to the thin plate 22 of the supporting member 21 while the sample holding member 3 is not displaced and not inclined.

In the state illustrated in FIG. 11B, the resonance frequency of the translational mode, which is a mode in which the sample holding member 3 is moved in the focus direction without being inclined, is denoted as f_{z2}. Because the sample holding member 3 is not inclined, the dominant factor in determining the resonance frequency f_{z2} of the translational mode is the bending stiffness of the thin plate 22. When the sample holding member 3 is not inclined, the supporting member 21 primarily supports the sample holding member 3 through the bending characteristics of the thin plate 22.

In the state illustrated in FIG. 11C, the resonance frequency of the inclination mode, which is a mode in which the sample holding member 3 is inclined around the Y-axis, is denoted as f_{θ2}. As the sample holding member 3 is inclined, the dominant factor in determining the resonance frequency f_{θ2} in the inclination mode is the tensile and compressive stiffness of the thin plate 22. When the sample holding member 3 is inclined, the supporting member 21 primarily supports the sample holding member 3 through the tensile and compression characteristics of the thin plate 22.

As described using FIGS. 11B and 11C, when the sample holding member 3 is inclined, the thin plate 22 is subjected to tensile and compressive forces in addition to the bending force. Therefore, when the tensile and compressive stiffness of the thin plate 22 is made greater than its bending stiffness, and by making the thin plate 22 flexible and easy to bend, the inclination of the sample holding member 3 can be suppressed.

FIG. 12 is a diagram illustrating a part of the supporting member 21, and is a diagram illustrating a portion of the thin plate 22 and some block members 23 (23a, 23b, and 23c) among the plurality of block members 23.

The thin plate 22 has a thickness (thin plate thickness), t, in the focus direction, and a width (thin plate width), w, in the radial direction of the sample holding member 3. An interval between the two thin plates 22 (thin plate interval) is v. A representative interval (block span) between the two block members 23 is s.

In the present embodiment, the thin plate thickness t is sufficiently small for the thin plate width w, the thin plate interval v, and the block span s. Therefore, the bending stiffness can be reduced, the tensile and compressive stiffness can be increased in the thin plate 22, and the inclination of the sample holding member 3 can be suppressed.

As described according to the first embodiment, when the resonance frequency for of the inclination mode is set to be equal to or greater than the resonance frequency f_{z2} of the translational mode, the inclination of the sample holding member 3 caused by the influence of resonance in the inclination mode can be suppressed when the sample holding member 3 is driven in the focus direction.

In the surface inspecting device 1 according to the present embodiment, based on the analysis result of numerical simulation conducted, when the thin plate thickness t is sufficiently small for the thin plate width w, the thin plate interval v, and the block span s, it was possible to obtain f_{θ2} such that f_{θ2}≥2f_{z2}. That is, in the present embodiment, it is possible to make the resonance frequency f_{θ2} of the inclination mode at least twice the resonance frequency f_{z2} of the translational mode.

According to the first embodiment, as illustrated in FIG. 6, the positions of the connection points between the two supporting members 12 (12a, 12b) and the sample holding member 3 are on the circumference of a circle with the radius L centered on the central axis 20. The position of the connection point between the supporting member 12 and the sample holding member 3 cannot exceed the radius R of the sample holding member 3. That is, according to the first embodiment, R>L. Since R>L, f_{θ1}<2f_{z1} is obtained from Equation (7). Accordingly, according to the first embodiment, the resonance frequency f_{θ1} of the inclination mode does not become twice or more than the resonance frequency f_{z1} of the translational mode.

The surface inspecting device 1 according to the present embodiment includes the supporting member 21, enabling the resonance frequency f_{θ2} of the inclination mode to be made at least twice the resonance frequency f_{z2} of the translational mode. Therefore, the surface inspecting device 1 according to the present embodiment can more effectively suppress the inclination of the sample holding member 3 in a direction (horizontal direction) perpendicular to the focus direction compared to the surface inspecting device 1 according to the first embodiment.

Both the thin plate 22 and the block member 23 can be formed by any method, for example, by machining. When the thin plate 22 and the block member 23 are formed by machining, the thin plate 22 and the block member 23 can be processed with high precision, so that the variation in the relative positions of the thin plate 22 and the block member 23 can be reduced. By reducing the variation, the balance of elastic forces of the supporting member 21 relative to the central axis 20 of the sample holding member 3 can be improved. Further, when the thin plate 22 and the block member 23 are formed by machining, the supporting member 21 can be connected to the sample holding member 3 and the rotation drive unit 19 with high precision. For these reasons, the effect of suppressing the inclination of the sample holding member 3 can be further increased by forming the thin plate 22 and the block member 23 by machining.

Note that the present invention is not limited to the embodiments described above, and various modifications are possible. For example, the embodiments described above are described in detail in order to describe the present disclosure in an easy-to-understand manner, and the present invention is not necessarily limited to aspects having all the configurations described above. Further, it is possible to replace a part of the configuration of one embodiment with the configuration of another embodiment. It is also possible to add the configuration of another embodiment to the configuration of one embodiment. Moreover, it is possible to delete a part of the configuration of each embodiment, or to add or replace another configuration thereto.

### REFERENCE SIGNS LIST

1: surface inspecting device
2: sample
3: sample holding member
4: spindle motor
5: turntable
6: frame
7: vertical driving stage
8: horizontal driving stage
9: illumination optical system
10: detection optical system
11: sample drive unit
12, 12a, 12b: supporting member
13: yoke
14: first magnet
15: second magnet
16: coil fixing member
17: first coil
18: second coil
19: rotation drive unit
20: central axis
21: supporting member
22: thin plate
23, 23a through 23p: block member
24: fixed part of block member

1. A surface inspecting device, comprising:
a sample holding member having a plate shape and capable of holding a sample;
a rotation drive unit configured to rotate the sample holding member;
a supporting member fixed to the sample holding member and the rotation drive unit and configured to support the sample holding member; and
a sample drive unit configured to displace the sample holding member relative to the rotation drive unit in a height direction, wherein
the supporting member includes a first supporting member and a plurality of second supporting members supporting the first supporting member,
the first supporting member is a plate-shaped member positioned between the sample holding member and the rotation drive unit, and is displaceable in the height direction relative to the sample holding member and the rotation drive unit, and
some of the plurality of second supporting members are fixed to the sample holding member, and the remainder are fixed to the rotation drive unit.

2. The surface inspecting device according to claim 1, wherein the first supporting member is the plate-shaped member having a plate surface facing the sample holding member.

3. The surface inspecting device according to claim 1, wherein the first supporting member includes a plurality of the plate-shaped members.

4. The surface inspecting device according to claim 1, wherein the first supporting member includes a plurality of the plate-shaped members parallel to each other.

5. The surface inspecting device according to claim 1, wherein the first supporting member includes an annular plate-shaped member.

6. The surface inspecting device according to claim 1, wherein the first supporting member includes an annular plate-shaped member that is divided into a plurality of parts in a circumferential direction.

7. The surface inspecting device according to claim 1, wherein the plurality of the second supporting members are arranged in an annular shape and are fixed to the sample holding member and the rotation drive unit alternately along a circumferential direction.

8. The surface inspecting device according to claim 1, wherein a fixed part of the second supporting member to the sample holding member or the rotation drive unit is a plane.
